(19) United States
(12) Patent Application Publication
(10) Pub. No.: US 2024/0346212 A1
(43) Pub. Date: Oct. 17, 2024

(54) METHOD AND SYSTEM FOR DETERMINING A FRICTIONAL COEFFICIENT OF AN AIRCRAFT ON A RUNWAY

(71) Applicant: Safran, Paris (FR)

(72) Inventors: Laurent Christian Vincent Roger Miralles, Moissy-Cramayel (FR); Christophe Bastide, Moissy-Cramayel (FR); Céline Colonna Ceccaldi, Moissy-Cramayel (FR); Vincent Hupin, Moissy-Cramayel (FR); Benoît Marty, Moissy-Cramayel (FR)

(21) Appl. No.: 18/292,129

(22) PCT Filed: Jul. 25, 2022
(86) PCT No.: PCT/FR2022/051492

§ 371 Date: Jan. 25, 2024

(30) Foreign Application Priority Data
Jul. 27, 2021 (FR) FR2108133

(51) Int. Cl. G06F 30/27; G08G 5/00

(52) U.S. Cl. CPC G06F 30/27; G08G 5/0017

(57) ABSTRACT

This method for determining a frictional coefficient of an aircraft on a runway includes the steps of:
producing a database of frictional coefficients simulated for various types of aircraft and various runway conditions by applying simulation data to models representing the braking of aircraft when landing, for various braking scenarios; and
predicting a frictional coefficient from real data of the aircraft for which the frictional coefficient is determined from data stored in the database.

The present invention relates, in general terms, to optimising the traffic on airports and reducing the number of runway closures which may have very great financial consequences for the airport operators.

In particular, the invention relates to determining conditions on runways of an airport in order to optimise the use of the runways, while meeting safety requirements.

The present time, airport operators must monitor the runway conditions. This monitoring is done either from radio reports supplied by pilots just after landing, or from measurements of frictional coefficients made by means of test lorries travelling on the runways, which requires closing the runways, or from sensors buried on the runway that determine the type and extent of any contaminants present on the runways, or from meteorological sensors, or from manual observations and measurements by a runway inspector, or from the manual combination of all these data.

Changes in current standards and regulations aim to improve the safety of operations on airport platforms and requires communicating the runway conditions of an airport to the competent authorities, to the air traffic control (or ATC) services and pilots.

Currently, the tools available and the methods that airports have available for evaluating the state of runways remain very subjective, imprecise and incomplete. The airport air traffic control services thus have to apply a greater margin than necessary, which is liable to cause unfounded closures of runways, with very great financial consequences for airport managers.

The aim of the invention is therefore to overcome these drawbacks and to supply a report on runway conditions for aircraft that is of increased reliability and relevance and can be used for optimising the use of runways by airport operators.

The object of the invention is therefore a method for determining a frictional coefficient of an aircraft on a runway that includes the steps of:
producing a database of frictional coefficients simulated for various types of aircraft and various runway conditions by applying simulation data to models representing the braking of aircraft when landing, for various braking scenarios; and
predicting a frictional coefficient from real data of the aircraft and from data stored in the database.

In other words, the data used for determining the runway conditions consist of the frictional coefficient extracted from a database in which frictional coefficients simulated from various braking scenarios are stored using models representing the braking of the aircraft on the runway, the frictional coefficient of the aircraft landing on a runway being predicted from the real data of the aircraft downloaded and from the data stored in the database.

The real data recorded in the onboard computers of the aircraft are recovered, decoded and filtered.

These data are used for stimulating the models to predict changes in the frictional coefficient.

During the filtering of the recovered data, the data are filtered by comparing the geolocation of the aircraft with corresponding runway-geolocation data.

Preferably, during filtering, a weighting is allocated to the data according to the type of aircraft and/or the frequency of data acquisition.

In one embodiment, the filtered data include geolocated and weighted data relating to the dynamics of the aircraft, to the type of aircraft and braking, and to a runway segment.

For example, during the prediction step, an algorithm of the “random forest”, decision tree or 8-layer neural network type is used.

It is possible to provide a step of comparing the real data with the simulation data in the form of time series to reconstruct a friction value as a function of time.

In one embodiment, the changes in the predicted frictional coefficient are compared with the simulated frictional coefficients to define that a maximum allowable frictional coefficient has been reached.

Advantageously, the frictional coefficients are standardised for pressure, braking energy and speed.

The method can furthermore include a step of storing data relating to predicted frictional coefficients modified by a frictional coefficient.

Another object of the invention is a system for determining a frictional coefficient of an aircraft on a runway, comprising a set of models representing the braking of aircraft, during landing thereof, a database of simulated frictional coefficients for various types of aircraft and various runway conditions, and a model for predicting a braking coefficient from real data of the aircraft for which the frictional coefficient is determined and from data stored in the database of simulated frictional coefficients.

Other aims, features and advantages of the invention will appear upon reading the following description, given solely as a non-limiting example, and made with reference to the appended drawings wherein:

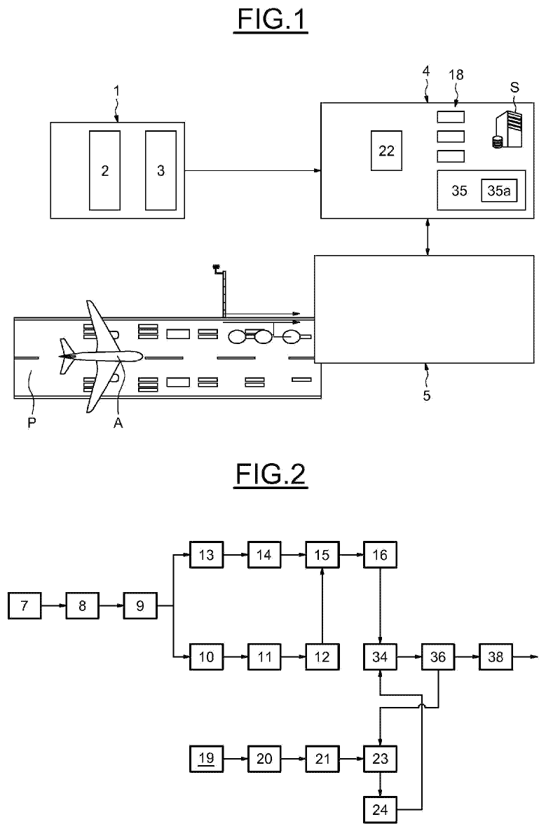

FIG. 1 is a diagram showing a runway of an airport equipped with a system for determining a frictional coefficient of the aircraft on the runway;

FIG. 2 illustrates the main phases of a method for determining a frictional coefficient of an aircraft on a runway according to the invention;

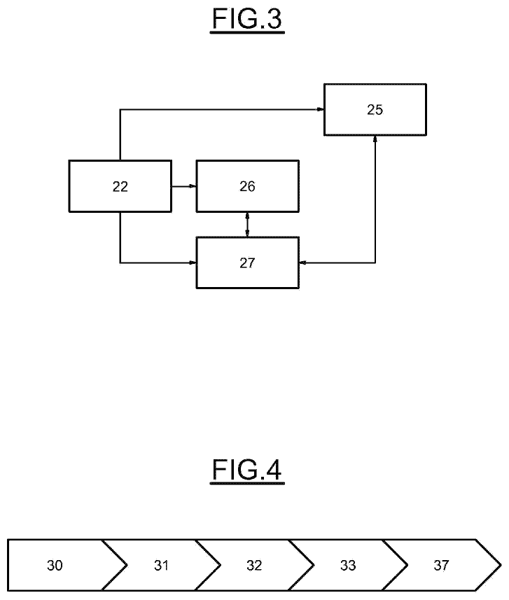

FIG. 3 shows the simulation architecture of the system of FIG. 2;

FIG. 4 is a diagram showing the various phases of training the models; and

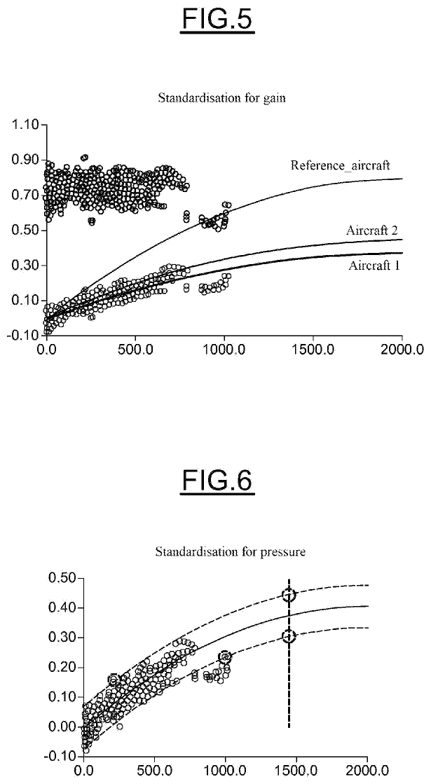

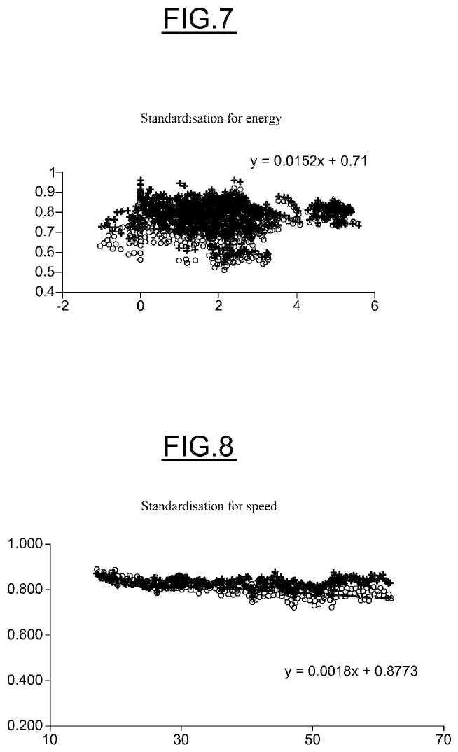

FIG. 5, FIG. 6, FIG. 7, and FIG. 8 illustrates the calculation of the standardised frictional coefficient used for characterising the runways.

Reference will be made first of all to FIG. 1, which illustrates the general principle of determining a frictional coefficient of an aircraft A when it is landing on a runway P.

The frictional coefficient is intended to be predicted from real data downloaded from the onboard computer of the aircraft in which data are recorded during flight, and in particular from data representing the dynamics of the aircraft, these data being compared with data coming from learning models for predicting the change in the frictional coefficient as a function of time and of the position of the aircraft on the runway.

As can be seen on FIG. 1, the aircraft are equipped with a braking-control unit 1 that communicates with onboard maintenance-assistance systems 2 to in particular deliver data relating to the operation of the braking system. These data are recorded in the aircraft onboard computer.

The maintenance-assistance systems 2 communicate with a telecommunication interface 3 in order to remotely transmit, wirelessly, during landing, the data recorded in the onboard computer and to supply them to a computing platform 4, comprising a server S in which the frictional coefficient of the aircraft is calculated and is then transmitted to a local platform 5 hosted at the airport operator.

The data recovered from the onboard computers are for example downloaded at the end of the braking phase, in real time and delayed, for example after the aircraft has reached the airport arrival gate.

With reference to FIG. 2, firstly, after storage in the onboard computer (step 7), the onboard data stored in the aircraft computer are transferred to the airline (step 8) and are stored on a server of the airline (step 9). The recovered data on the data that are recorded in the computer by virtue of the certification. It is a case at a minimum of the QAR (standing for “quick access recorder”) frames and preferably the SAR frames, to the binary file format.

These data can then be transferred from the airline server directly to the computing server 4 dedicated to calculating the runway conditions (step 10) and are stored therein (step 11). During the following step 12, these data are decoded.

In a variant, the raw data extracted from the airline server can be decoded before transfer thereof to the computing platform 4 so as to extract parameters relating to a precise flight phase (step 13), and a file is sent to the server of the platform 4 (step 14).

During the following step 15, the data decoded during step 12 after transfer to the platform 4 or transferred during step 14 after decoding are stored in the server of the platform 4 and are then filtered (step 16).

In all cases, the non-decoded raw data or the decoded data are transmitted to the server S of the platform 4, preferably using an SFTP link.

Depending on the type of aircraft, according to the airline and the destination airport, the information downloaded from the aircraft computer is sent to the airline server on the ground during step 8 using a communication network or manually, during the taxiing phase or on arrival at a disembarking gate. These operations can be manual or be automated using scripts.

For example, the downloaded data can comprise the weight of the aircraft, the centre of gravity of the aircraft, the type of aircraft, the rotation speed of the wheels, the throttle control angle, the speed of the aircraft, the deceleration of the aircraft, the status of the braking system, the status of the thrust reverser, the status of the spoiler, the degree to which the brake pedal is pressed, the pressure of the braking system and the movement of the brake piston, the status of the weight on wheels, inertial data, the aircraft GPS geolocation data, the type of brake, the flight phase, timestamping data, the status of the autobraking and the controlled pressure of the braking system.

For some types of aircraft, it is possible furthermore to obtain the following parameters: the status of the antiskid system, the antiskid current, the state of the automaton, the consolidated wheel speed and the vertical force.

The decoding implemented during step 12 comprises the chopping of the data frames timewise to include only the flight phase from touchdown to an aircraft speed of less than 20 knots (37 km/hour).

In other words, the decoding delivers the landing data as long as the speed of the aircraft is above 20 knots or in the absence of any indicator indicating that the braking phase has ended.

A time file with all these parameters is stored on the server S of the computing platform 4.

The server of the computing platform firstly proceeds with a sampling of the data, at a frequency for example of between 1 hertz and several hundreds of hertz according to the various types of aircraft and configuration.

The data transferred to the server of the local platform 5 are filtered, during step 16, so as in particular to recover the data relating to the dynamics and geolocation of the aircraft.

It is a case in particular of the speed of the aircraft, the status of the braking system, the status of the thrust reverser, the status of the spoiler, the state of the autobrake, the degree to which the brake pedal is pressed, the flight phase, data relating to the aircraft weight on wheels and data extracted from a GPS global positioning system.

Firstly, the decoded GPS data are compared with geolocation data of runway/airport pairs available in the database of the airport operator. If the location does not correspond, the data is abandoned.

Moreover, a general weighting is allocated for each set of flight data according to the type of aircraft and the type of frame (QAR, SAR, etc) using a parameterisable configuration table recorded on the computing platform 4. This table allocates a coefficient adjusted according to the type of aircraft and the acquisition frequency. For example, for a type of aircraft the data frame of which includes a small number of data, for example for a type of aircraft the frame of which has only data relating to the braking pressure but does not include data relating to the speed of the wheel, the weighting is lower than if all the data are available.

Likewise, a frame sampled at 1 hertz, such as a QAR frame, is allocated a lower coefficient than an SAR frame at 4 hertz.

According to the various partial input parameters, for the data considered to be valid, a vector of the various braking segments with their type and their weighting coefficient is generated, rejecting the phases before touchdown and after the aircraft has reached a speed of less than 20 knots.

In this way, as an output, the following vectors are obtained:
Filtered_data: (runway_ID; type_aircraft; segment n; type of braking;
weighting coefficient), and
Segment n (data for μ; time; position)
wherein
Filtered_data designates the filtered output data;
type_aircraft designates the type of aircraft;
runway_ID is a geolocation identifier of the runway;
segment n corresponds to a segment of the runway
data for μ comprises the following dynamic data: deceleration of the aircraft; speed of the aircraft; speed of the wheels, pressure of the braking system; control of the brake pedal; autobraking (step 10).

In addition, referring once again to FIG. 1, the platform 4 comprises a certain number of models 18 representing the braking. It is a case in particular of a model of the aircraft representing its dynamics according to its aerodynamic characteristics, simulating its flight commands, its weight, its centre of gravity, the thrust of its engine, the effect of the thrust reversal and the spoiler, a model of the braking system and of the regulation thereof, and a runway model representing the maximum allowable friction and the friction resulting from the braking forces.

These models 18 constitute a closed-loop simulation environment.

With reference to FIG. 2, braking simulation scenarios are moreover established (step 19) and the simulation data are transmitted to the platform 4 (step 20) to be stored on a database of simulated frictional coefficients 35a of the computing server of the platform (step 21).

The platform 4 thus includes a simulation data base 22 corresponding to various braking scenarios varying various test conditions related to the dynamics of the aircraft, to its characteristics, to the instructions of the pilot and to runway conditions, relating in particular to the maximum allowable frictional coefficient, etc.

These data comprise for example simulation data relating to the type of aircraft, in particular to various aircraft weights or various landing speeds, to the breaking, in particular various braking profiles, various brake-pedal commands, autobraking, thrust reverser and spoilers, and various maximum allowable frictional coefficients. Some of these scenarios result from a parameterising as close as possible to real flights.

During the following step 23, the simulation scenario data are used for training models representing the braking of aircraft when landing, for various braking scenarios. The trained models are next stored in the server of the platform 4 (step 24).

As illustrated in FIG. 3, the simulation data relating to the runway conditions stored in the database 22 are supplied to a runway model 25.

With reference to FIG. 3, the simulation data relating to the type of aircraft are transmitted to an aircraft model 26 while the simulation data relating to the braking are transmitted to a model 27 of the braking system.

For each scenario, several simulation speeds are produced between several hundreds of hertz and 1 hertz.

With reference to FIG. 4, the models are therefore implemented, trained and tested according to a phase that therefore begins with a phase 30 of loading simulation data, for various braking scenarios, a flight chopping phase 31, by decoding to keep the touchdown data up to a limit speed value fixed for example at 20 knots, and a step 32 of processing the data in which these data are digitised and additional variables are calculated.

The following step 33 corresponds to a training of the models with the simulation data so as to obtain, as an output, simulated frictional coefficient values.

Moreover, during the following step 34 (FIG. 2), the real data of the aircraft are recovered, which are decoded and then filtered and injected into a prediction module 35 of the platform 4. The prediction compares the real data file with the data corresponding to the scenario of the training model, in time series, to reconstruct the friction value at each time step. The values of the frictional coefficients are next stored in memory in a database 35a of simulated frictional coefficients, for various types of aircraft and various runway conditions (step 36).

The prediction algorithm uses either an algorithm of the random forest type, for example with a smoothing effect over a range of 100 to 300 samples according to the refresh rate of the input data, or on a neural network, for example with eight stages.

Finally, the step 33 of training the models is followed by a phase 37 of evaluating the models.

Various methods for evaluating the models are used, for example by regression, by classification or real-time prediction.

In particular, to evaluate the models on the simulation data, the mean error on each flight and each wheel is evaluated, for each scenario. To have the global error of all the models, the results are averaged for all the data. Furthermore, use is made of the maximum error MAE and the standard deviation of the efficacy of the model using the following equation:

$$MAE = \frac{1}{n} \times {\sum }_{t = 0}^{tf} \vert - {y}_{t} \vert$$

with:
MAE: mean absolute error;
n: number of time steps of the scenario;
t: time step;
ŷ: value of the predicted frictional coefficient μ;
yt: theoretical value of μ.

Moreover, the trend of the resulting friction curve is compared with the result of the scenarios of the training model to define whether or not the maximum allowable frictional coefficient has been reached by the runway.

If this maximum value of the frictional coefficient has not been reached, a characterisation of the maximum frictional coefficient seen by the aircraft is defined.

The maximum value of the frictional coefficient μₘₐₓ is however on the one hand in practice difficult to obtain without using powerful and complex computing means; and on the other hand is actually available in less than 1% of cases. Such is in particular the case when the coefficient μₘₐₓ is calculated according to the slipping.

A standardised braking coefficient value un is thus calculated, in order to make comparisons between aircraft and between braking points.

To do this, for each braking point, the prediction algorithm supplies a frictional coefficient μ associated with:
a pressure in the braking system (p),
a speed of the aircraft with respect to the runway (v),
a braking energy that is the mean of the energy during a given period of time—here tested at one second (E).

The frictional coefficient is standardised for braking gain (FIG. 5), for braking pressure (FIG. 6) and for braking energy (FIG. 7).

With reference to FIG. 5, the coefficient μ is first of all increased by homothetic transformation of the mean braking gain profile to pass from the aircraft in consideration (Aircraft 1 or Aircraft 2) to a reference aircraft (Reference_Aircraft).

The coefficient μₙₕ thus obtained is next projected according to the trend curve onto a straight line at a braking pressure p equal to 1450 psi to obtain a frictional coefficient μₙₚ equivalent to a reference pressure (FIG. 6).

In the plane (μ,E) the coefficient μₙₚ is projected on a straight line to the value E=5MJ (for one second) to obtain a friction equivalent to reference pressure and energy (FIG. 7).

In the plane (μ,v) the coefficient μₙₑ is projected on a straight line to the value v=25.6 m/s to obtain a friction standardised to reference pressure, energy and speed (FIG. 8).

This standardisation step thus consists in processing the frictional coefficient so as to characterise it in a reference frame of predetermined pressure, braking energy and speed values, so that the friction force solely relates to the runway.

This standardised value of the frictional coefficient is then used to make comparable acquisitions and to use a characterisation of the runway or runway segment.

The result of the predictions modified by a weighting coefficient is stored in a file and then stored in a server.

Finally, the method furthermore includes a step 38 of transferring the results of the calculations of frictional coefficients. They can thus be used by other applications, such as the one that is used by the platform 5 for calculating airport runway conditions, or other tools for optimising operational costs, or to embedded applications for anticipating braking procedures.

1. A method for determining a frictional coefficient of an aircraft on a runway, wherein the method includes the steps of:
producing a database of frictional coefficients simulated for various types of aircraft and various runway conditions by applying simulation data to models representing braking of aircraft when landing for various braking scenarios; and
predicting a frictional coefficient from real data of the aircraft for which the frictional coefficient is determined from data stored in the database.

2. The method according to claim 1, wherein the real data recorded in an onboard computer of the aircraft are recovered, and wherein the recovered real data are decoded and the decoded real data are filtered.

3. The method according to claim 2, wherein, during the filtering of the recovered real data, the data are filtered by comparing a geolocation of the aircraft with corresponding runway-geolocation data.

4. The method according to claim 3, wherein, during filtering, a weighting is allocated to the data according to the type of aircraft and/or a frequency of data acquisition.

5. The method according to claim 4, wherein the filtered data include geolocated and weighted data relating to dynamics of the aircraft, to the type of aircraft and braking, and to a runway segment.

6. The method according to claim 1, wherein, during the prediction step, an algorithm of random forest, decision tree, or 8-layer neural network type is used.

7. The method according to claim 6, wherein the real data are compared with the simulation data as a time series to reconstruct a frictional coefficient value as a function of time.

8. The method according to claim 1, wherein a change in the predicted frictional coefficients is compared with the simulated frictional coefficients to define that a maximum allowable frictional coefficient has been reached.

9. The method according to claim 1, wherein the frictional coefficients are standardised for pressure, braking energy, and speed.

10. The method according to claim 8, further comprising a step of storing data relating to predicted frictional coefficients modified by a weighting coefficient.

11. A system for determining a frictional coefficient of an aircraft on a runway, wherein the system comprises:
a set of models representing braking of aircraft during landing thereof;
a database of simulated frictional coefficients for various types of aircraft and various runway conditions; and
a module for predicting a braking coefficient from real data of the aircraft for which the frictional coefficient is determined and from data stored in the database of simulated frictional coefficients.
